(19) United States
(12) Patent Application Publication
(10) Pub. No.: US 2025/0181907 A1
(43) Pub. Date: Jun. 5, 2025

(54) HYBRID ELECTRONIC-IONIC CIRCUIT FOR IMPLEMENTING A BIO-PLAUSIBLE THREE-FACTOR SYNAPTIC PLASTICITY RULE

(71) Applicant: Massachusetts Institute of Technology, Cambridge, MA (US)

(72) Inventors: Bilge Yildiz Botterud, Cambridge, MA (US); Mantao Huang, Cambridge, MA (US); Jesus Del Alamo, Lincoln, MA (US); Ju Li, Weston, MA (US); Michale S. Fee, Lexington, MA (US)

(73) Assignee: Massachusetts Institute of Technology, Cambridge, MA (US)

(21) Appl. No.: 18/961,936

(22) Filed: Nov. 27, 2024

Related U.S. Application Data
(60) Provisional application No. 63/605,029, filed on Dec. 1, 2023.

(51) Int. Cl. G06F 3/01; G01N 27/414

(52) U.S. Cl. CPC G06N 3/065; G11C 11/54; H10N 70/245; H10N 70/253; H10N 70/8416; H10N 70/8833; H01G 9/032

(57) ABSTRACT

Disclosed herein is a hybrid electronic-ionic circuit comprising a first electrochemical ionic synapse (EIS), wherein in response to a non-zero electrical stimulus applied to the first EIS, the first EIS operates in a volatile operation mode to generate a delayed-onset self-resetting signal; and a second EIS, wherein in response to a non-zero electrical stimulus applied to the second EIS, the second EIS operates in a non-volatile operation mode and a conductance of the second EIS controls a strength of an output of the second EIS. In some embodiments, the non-zero electrical stimulus for the first EIS comprises one or more of a context signal or a variability signal. In some embodiments, the non-zero electrical stimulus for the second EIS comprises one or more of the delayed-onset self-resetting signal, a reward signal, or a context signal.

### CROSS-REFERENCE SECTION

This application claims the benefit under 35 U.S.C. § 119 of U.S. Provisional Patent Application No. 63/605,029 filed on Dec. 1, 2023, which is hereby incorporated herein by reference in its entirety.

### STATEMENT REGARDING FEDERALLY SPONSORED RESEARCH

N/A

### BACKGROUND

The rapid rise in energy demand for computing prompts a search for advanced computing paradigms. The exploration and development of innovative architectures with brain-guided learning rules have the potential to offer substantial enhancements in energy efficiency and performance. The recent advance of electrochemical ionic synapse (EIS) has shown their promise as programmable synaptic weights in deep learning accelerators.

### SUMMARY

Beyond accelerating deep neural networks, EIS have the potential to translate understandings and discoveries in neuroscience to the design of brain-guided, energy-efficient hardware, machine intelligence platforms. Disclosed herein is a hybrid electronic ionic circuit, which emulates biological learning of a complex vocal. In one example embodiment, a local hybrid electronic ionic circuit operating in accordance with the concepts, structure and techniques described herein emulates the biological learning of a complex vocal behavior in the songbird. Herein, a “local circuit” refers to a circuit that interacts with local signals that enter and exit (i.e., go in and out of) an associated synapse circuit. That is, the term “local” conveys that the scope of each local circuit is for one synapse.

The hybrid electronic ionic circuit uses a coincidence triggered delayed-onset, self-resetting signal generator to modulate the synaptic strength of a non-volatile electrochemical ionic synapse (EIS), to implement a bio-plausible three-factor synaptic plasticity rule. The plasticity rule is based upon a three-factor Hebbian mechanism that underlies the vocal learning of songbirds.

Further disclosed herein is a technique for applying an EIS in its volatile operation mode, to implement a delayed-onset, self-resetting signal generator. The generated signal may be suitable as an eligibility trace for reinforcement learning. By forming a voltage divider circuit on a gate of the EIS, a coincidence detector can be implemented to trigger the signal generation. In embodiments, the coincidence detector is implemented with one or more logic gates, for example.

According to one aspect of the disclosure, a hybrid electronic-ionic circuit comprises a first electrochemical ionic synapse (EIS), wherein in response to a non-zero electrical stimulus applied to the first EIS, the first EIS operates in a volatile operation mode to generate a delayed-onset self-resetting signal; and a second EIS, wherein in response to a non-zero electrical stimulus applied to the second EIS, the second EIS operates in a non-volatile operation mode and a conductance of the second EIS controls a strength of an output of the second EIS.

In some embodiments, the non-zero electrical stimulus for the first EIS comprises one or more of a context signal or a variability signal. In some embodiments, the non-zero electrical stimulus for the second EIS comprises one or more of the delayed-onset self-resetting signal, a reward signal, or a context signal. In some embodiments, each EIS further comprises: a channel provided from one or more materials with a tunable electronic conductivity that is determined by an ion concentration; an electrolyte disposed over the channel; and an ion reservoir disposed over the electrolyte, wherein in response to a non-zero electrical stimulus one or more ions are released from the ion reservoir.

In some embodiments, each EIS further comprises: a channel provided from one or more materials with a tunable electronic conductivity that is determined by an ion concentration; an electrolyte disposed over the channel; an ion reservoir disposed over the electrolyte, wherein in response to a non-zero electrical stimulus one or more ions are released from the ion reservoir; and the channel comprises about 10 nm of tungsten trioxide (WO₃) and the electrolyte comprises about 7 nm to about 21 nm of yttria-stabilized zirconia (YSZ). In some embodiments, each EIS further comprises: a channel provided from one or more materials with a tunable electronic conductivity that is determined by an ion concentration; an electrolyte disposed over the channel; an ion reservoir disposed over the electrolyte, wherein in response to a non-zero electrical stimulus one or more ions are released from the ion reservoir; and each EIS further comprises: a source disposed over a first end of the channel; a drain disposed over a second opposing end of the channel; and a gate disposed over the ion reservoir. In some embodiments, each EIS further comprises: a channel provided from one or more materials with a tunable electronic conductivity that is determined by an ion concentration; an electrolyte disposed over the channel; an ion reservoir disposed over the electrolyte, wherein in response to a non-zero electrical stimulus one or more ions are released from the ion reservoir; and each EIS further comprises: a source disposed over a first end of the channel; a drain disposed over a second opposing end of the channel; and a gate disposed over the ion reservoir; and the source comprises chromium (Cr) or gold (Au), the drain comprises Cr or Au, and the gate comprises about 15 nm of palladium (Pd). In some embodiments, each EIS further comprises: a channel provided from one or more materials with a tunable electronic conductivity that is determined by an ion concentration; an electrolyte disposed over the channel; an ion reservoir disposed over the electrolyte, wherein in response to a non-zero electrical stimulus one or more ions are released from the ion reservoir; each EIS further comprises: a source disposed over a first end of the channel; a drain disposed over a second opposing end of the channel; and a gate disposed over the ion reservoir; and a voltage divider circuit is disposed over the gate to form a coincidence detector (AND-gate).

According to another aspect of the disclosure, a circuit comprises one or more hybrid electronic-ionic circuits. In some embodiments, one or more hybrid electronic ionic circuits comprise: a first electrochemical ionic synapse (EIS), wherein in response to an applied electrical stimulus the first EIS operates in a volatile operation mode to generate a delayed-onset self-resetting signal; and a second EIS, wherein in response to an applied electrical stimulus the second EIS operates in a non-volatile operation mode and a conductance of the second EIS controls a strength of an output of the second EIS. In some embodiments, the circuit comprises one or more context generators configured to generate a context signal, wherein a first context generator is configured to connect to the first EIS and a second context generator is configured to connect to the second EIS. In some embodiments, the circuit comprises one or more variability generators configured to generate a variability signal, wherein a first variability generator is configured to connect to the first EIS. In some embodiments, the circuit comprises one or more reward signal generators configured to generate a reward signal, wherein a first reward signal generator is configured to connect to the second EIS. In some embodiments, the circuit comprises one or more motor systems, wherein the context signal, variability signal, and output of the second EIS are transmitted to the motor systems.

In some embodiments, the applied electrical stimulus for the first EIS comprises one or more of the context signal or the variability signal. In some embodiments, the applied electrical stimulus for the second EIS comprises one or more of the delayed-onset self-resetting signal, the reward signal, or the context signal. In some embodiments, each EIS further comprises: a channel provided from one or more materials with a tunable electronic conductivity that is determined by an ion concentration; an electrolyte disposed over the channel; and an ion reservoir disposed over the electrolyte, wherein in response to a non-zero electrical stimulus one or more ions are released from the ion reservoir.

In some embodiments, each EIS further comprises: a channel provided from one or more materials with a tunable electronic conductivity that is determined by an ion concentration; an electrolyte disposed over the channel; an ion reservoir disposed over the electrolyte, wherein in response to a non-zero electrical stimulus one or more ions are released from the ion reservoir; and each EIS further comprises: a source disposed over a first end of the channel; a drain disposed over a second opposing end of the channel; and a gate disposed over the ion reservoir. In some embodiments, each EIS further comprises: a channel provided from one or more materials with a tunable electronic conductivity that is determined by an ion concentration; an electrolyte disposed over the channel; an ion reservoir disposed over the electrolyte, wherein in response to a non-zero electrical stimulus one or more ions are released from the ion reservoir; each EIS further comprises: a source disposed over a first end of the channel; a drain disposed over a second opposing end of the channel; and a gate disposed over the ion reservoir; and a voltage divider circuit is disposed over the gate to form a coincidence detector (AND-gate).

According to another aspect of the disclosure, a hybrid electronic-ionic circuit, comprises an electrochemical ionic synapse (EIS) configured to receive one or more applied electrical stimulus, wherein in response to a coincidence of one or more applied electrical stimulus the EIS operates in a volatile operation mode to generate a time-varying self-resetting signal.

In some embodiments, the applied electrical stimulus for the EIS comprises one or more of a context signal or a variability signal. In some embodiments, each EIS further comprises: a channel provided from one or more materials with a tunable electronic conductivity that is determined by an ion concentration; an electrolyte disposed over the channel; and an ion reservoir disposed over the electrolyte, wherein in response to a non-zero electrical stimulus one or more ions are released from the ion reservoir.

In some embodiments, each EIS further comprises: a channel provided from one or more materials with a tunable electronic conductivity that is determined by an ion concentration; an electrolyte disposed over the channel; an ion reservoir disposed over the electrolyte, wherein in response to a non-zero electrical stimulus one or more ions are released from the ion reservoir; and each EIS further comprises: a source disposed over a first end of the channel; a drain disposed over a second opposing end of the channel; and a gate disposed over the ion reservoir. In some embodiments, each EIS further comprises: a channel provided from one or more materials with a tunable electronic conductivity that is determined by an ion concentration; an electrolyte disposed over the channel; an ion reservoir disposed over the electrolyte, wherein in response to a non-zero electrical stimulus one or more ions are released from the ion reservoir; each EIS further comprises: a source disposed over a first end of the channel; a drain disposed over a second opposing end of the channel; and a gate disposed over the ion reservoir, wherein a voltage divider circuit is disposed over the gate to form a coincidence detector (AND-gate). In some embodiments, each EIS further comprises: a channel provided from one or more materials with a tunable electronic conductivity that is determined by an ion concentration; an electrolyte disposed over the channel; an ion reservoir disposed over the electrolyte, wherein in response to a non-zero electrical stimulus one or more ions are released from the ion reservoir; each EIS further comprises: a source disposed over a first end of the channel; a drain disposed over a second opposing end of the channel; and a gate disposed over the ion reservoir, wherein a voltage divider circuit is disposed over the gate to form a coincidence detector (AND-gate), and wherein a conductance of the channel can be read out by measuring current flowing through the channel with a fixed bias voltage across the source and the drain or by the voltage divider circuit.

### DESCRIPTION OF THE SEVERAL VIEWS OF THE DRAWINGS

The manner and process of making and using the disclosed embodiments may be appreciated by reference to the figures of the accompanying drawings. It should be appreciated that the components and structures illustrated in the figures are not necessarily to scale, emphasis instead being placed upon illustrating the principals of the concepts described herein. Like reference numerals designate corresponding parts throughout the different views. Furthermore, embodiments are illustrated by way of example and not limitation in the figures, in which:

FIG. 1A is a schematic diagram of a system which includes a hybrid ionic-electronic circuit;

FIG. 1B is a functional schematic diagram of a hybrid ionic-electronic circuit;

FIG. 2 is a schematic diagram of an example embodiment of a hybrid ionic-electronic circuit;

FIG. 3 is a diagram of a prior art electrochemical ionic synapse (EIS) appropriate for use in a hybrid ionic-electronic circuit;

FIG. 4 is a cross-sectional side view of a prior art EIS for a hybrid ionic-electronic circuit;

FIG. 5 is a top view of a prior art EIS for a hybrid ionic-electronic circuit;

FIG. 6 is a schematic diagram of a brain of a prior art songbird, illustrating song-related neural circuits and connections;

FIG. 7 is a graph of gate-to-drain voltage (V_{GD}) vs. time, illustrating a signal waveform on a gate of a volatile EIS;

FIG. 8 is a graph of normalized conductance (G) vs. time (ms), illustrating a conductance trace when a 100 ms pulse is applied to the gate of a volatile EIS;

FIG. 9 is a graph of time decay (t_{decay}) (s) vs. Vᵣₑₛₜ (V), illustrating the time it takes for the conductance to reduce to 50% from its highest value (t_{decay});

FIG. 10 is a graph of normalized conductance (G) vs. time (ms), illustrating a conductance trace when a voltage pulse is applied to the gate of a volatile EIS; and

FIG. 11 is a graph of rise time (tᵣᵢₛₑ) (s) vs. Vₚ (V), disclosing the time it takes for the conductance to rise to 50% of the highest level (tᵣᵢₛₑ).

### DETAILED DESCRIPTION

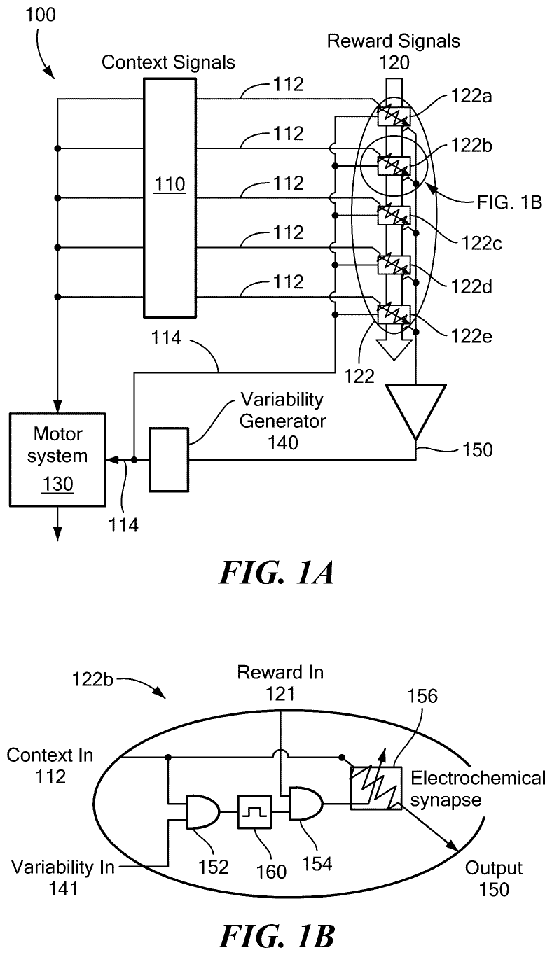

FIG. 1A is a schematic diagram of a system 100 comprising a hybrid ionic-electronic circuit 122 (also sometimes referred to herein as a local circuit 122) which receives input signals from a context signal source 110 (also sometimes referred to herein as a context signal generator 110) and a variability signal source 140 (also sometimes referred to herein as a variability signal generator 140). Context signals 112 are generated by context signal generator 110 and transmitted, coupled, or otherwise provided to one or more hybrid ionic-electronic circuits 122 with five (5) hybrid ionic-electronic circuits 122a, 122b, 122c, 122d, 122e being shown in the example embodiment of FIG. 1A. Variability signals 141 from the variability signal generator 140 are generated and transmitted, coupled, or otherwise provided to one or more of the hybrid ionic-electronic circuits 122.

One or more of the hybrid ionic-electronic circuits 122 also coupled to receive reward signals 121. Reward signals 121 may be generated by (or otherwise provided from) a reward signal source 120 (also sometimes referred to herein as a reward signal generator 120).

An output 150 of hybrid ionic-electronic circuit 122 is coupled to variability signal generator 140 via signal path 150 which may optionally an optional amplifier 151 and other signal conditioning circuitry (e.g., one or more filters, not shown in FIG. 1A). Variability signal generator 140 operates on the signal provided thereto and provides variability signals 114 to a motor system 130. In an embodiment, a motor system refers to the central and peripheral structures in a nervous system that support motor behavior and/or movement of the organism (i.e., the songbird). For example, the signals 114 and 130 could feed into the motor neurons that in turn control the contraction of the songbird's muscles. Accordingly, the motor system 130 could refer to any output the system aims to learn. In another example embodiment, the motor system could be a robotic arm and the output could be movement of the robotic arm.

It is also possible to have multiple local circuits that share the same context signal 112 and/or the same variability signal 114. The output from the local circuit 122 as well as, variability signals 114 and context signals 112 are transmitted, coupled, or otherwise provided to the motor system 130.

The hybrid ionic-electronic circuit 122 implements the three-factor-learning rule by tracking the time coincidence of the context, variability and reward signals 112, 121, 114 and also controls the synaptic strength as a result.

In this example embodiment, hybrid ionic-electronic circuit 122 includes: a first hybrid ionic-electronic circuit 122a, a second hybrid ionic-electronic circuit 122b, a third hybrid ionic-electronic circuit 122c, a fourth hybrid ionic-electronic circuit 122d, and a fifth hybrid ionic-electronic circuit 122e. While five hybrid ionic-electronic circuits are disclosed herein, after reading the disclosure provided herein, those of ordinary skill in the art will appreciate that in other embodiments hybrid ionic-electronic circuit 122 may comprise fewer or more than five (5) hybrid ionic-electronic circuits. The number of hybrid ionic-electronic circuits may be selected, for example, based upon the complexity of the application or system in which the hybrid ionic-electronic circuit will be used. For example, in a more complex application additional hybrid ionic-electronic circuits may be included, while for a simpler application fewer hybrid ionic-electronic circuits may be included.

In an example embodiment, the hybrid ionic-electronic hardware architecture emulates the biological learning of a complex vocal behavior in the songbird.

Referring now to FIG. 1B, shown is an example functional schematic diagram which illustrates the function/operation of one of hybrid ionic-electronic circuits 122a-122e (also sometimes referred to herein as “local circuits 122a-122e”) in the system of FIG. 1A. Taking local circuit 122b as representative of local circuits 122a, 122c-122e, local circuit 122b includes a first logical AND gate 152 having a pair of inputs with a first one of the inputs coupled to receive a context signal 112 and a second one of the inputs coupled to receive a variability signal 114. Local circuit 122b further comprise a second logical AND gate 154 having a pair of inputs, with a first one of the inputs coupled to receive a reward signal 121 and a second one of the inputs coupled to receive an output signal from an output of first logical AND gate 152.

An output of second logical AND gate 154 is coupled to a first input of an electrochemical synapse circuit 156 (or more simply, an electrochemical synapse 156). A second input of electrochemical synapse 156 is coupled to receive context signal 112. In response to the signals provided thereto, electrochemical synapse 156 provides an output signal 150.

As noted above, hybrid ionic-electronic circuits 122 may be used to implement the three-factor-learning rule by tracking a time coincidence of the context, variability and reward signals 112, 114, 121 and controls the synaptic strength as a result. As illustrated in FIG. 1B, when the context and variability signals 112, 114 are of sufficient strength (e.g., have an amplitude such as a voltage level or voltage amplitude which meets or exceeds a predetermined threshold) logical AND gate 152 provides a logical 1 output signal at an output thereof. Logical AND gate 152 thus detects or otherwise determines coincidence of context signals 112 and variability signals 114 (i.e., Logical AND gate 152 determines when both the context and variability signals have amplitudes which exceed a threshold value and in response thereto logical AND gate 652 outputs a signal having a logic 1 value).

In one embodiment, for example, when context and variability signals 112, 114 are of sufficient strength to be recognized as “logical 1s” logical AND gate 152 provides a logical 1 output signal at an output thereof. For reasons which will become clear after reading the description further below, logical AND gate 152 is thus said to establish a “time window” (sometimes referred to as an eligibility time window) represented by reference numeral 160 in FIG. 1B).

Eligibility time window 160 is defined by the amplitudes (e.g., voltage levels) of the context and variability signals 112, 114 provided at the inputs of logical AND gate 152. When either of the context and variability signals 112, 114 drop below a threshold signal strength, logical AND gate 152 outputs a logical 0 output signal and thus the eligibility time window 160 is said to be closed. That is, when logical AND gate 152 outputs a logical 1 signal, the eligibility time window is said to be open. Conversely, when logical AND gate 152 outputs a logical 0 output signal, the eligibility time window 160 is said to be closed.

If one or more reward signals 121 having an amplitude which exceeds a predetermined threshold is provided to an input of logical AND gate 156 while an eligibility time window is open (i.e. when logical AND gate 152 provides a 1 at the output thereof), the reward signals are said to arrive during the optimal timing window. Reward signals 121 having an amplitude which exceeds a predetermined threshold that arrive during the optimal timing window strengthen the synaptic connection of electrochemical synapse 126. On the other hand, reward signals 121 having an amplitude which exceeds a predetermined threshold which arrive before the eligibility time window is open or which arrive after the eligibility time window has closed have a diminishing effect on the strength of the synaptic connection of electrochemical synapse 126.

A non-zero electrical stimulus for the electrochemical synapse 156 may be provided by one, some or all of: a (non-zero) context signal 112; and/or a (non-zero) variability signal 114; and/or a (non-zero) reward signal.

When the context signal 112, variability signal 114 and reward signal 121 all concurrently have an amplitude above an amplitude threshold value (i.e., there is coincidence of context signals 112 and variability signals 114), the output signals from AND gates 152, 154 are both a logical 1. Thus, a context signal 112 and a logic 1 signal from AND gate 154 are concurrently provided to electrochemical synapse 156.

Electrochemical synapse 156 receives the signals provided thereto and generates an output signal 150 having a maximum or near maximum signal strength (e.g., a maximum or near maximum output signal amplitude is generated).

When one or more of context signal 112, variability signal 114 and reward signal 121 do not concurrently have an amplitude above an amplitude threshold (in which case the output signal from AND gate 154 is a logical 0) there is no coincidence of signals (e.g., no coincidence of context and variability signals 112, 114), and electrochemical synapse 156 generates an output signal 150 having a strength which is diminished compared with the maximum or near maximum signal strength. On the other hand, if a reward signal is provided to an input of logical AND gate 156 while an eligibility time window is closed, it has a diminishing effect. The hybrid ionic-electronic hardware architecture illustrated in FIG. 1B emulates biological learning of a complex system. In one embodiment, hybrid ionic-electronic hardware architecture illustrated in FIG. 1B emulates vocal behavior in a songbird.

By using hybrid ionic-electronic circuits 122 as building blocks and harnessing their intrinsic ion dynamics, a bio-plausible three-factor synaptic plasticity rule can be implemented with a relatively small footprint. For example, a hybrid ionic-electronic circuit may contains one transistor and one electrochemical synapse 156 as active components. This potentially leads to about a 10,000 (+/−100) times reduction in energy consumption compared to digital CMOS counterparts. Accordingly, when arranged in a system such as the system of FIG. 1A, a hybrid ionic-electronic circuit and an EIS can emulate a three-factor learning rule with a suitable shape of synaptic tuning based on the timing of the reward signal.

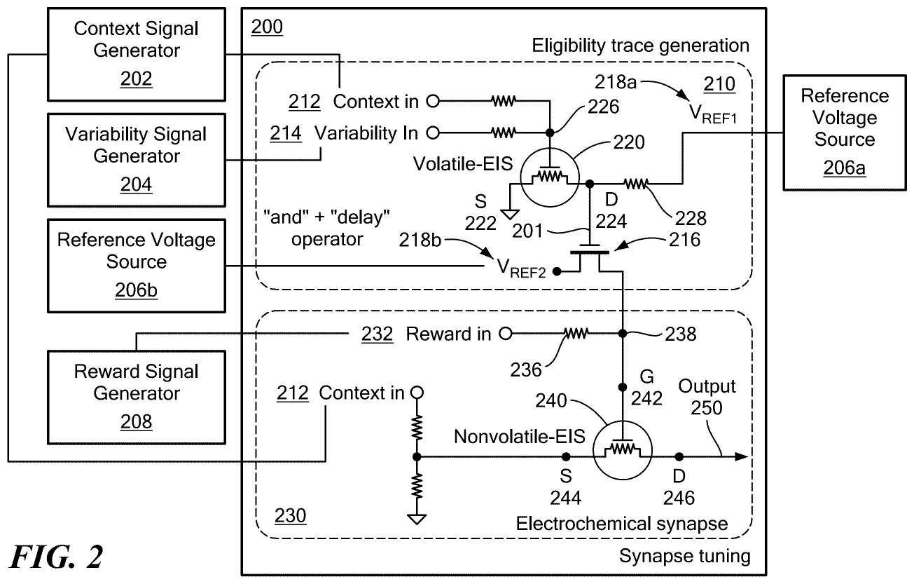

Referring now to FIG. 2, a hybrid ionic-electronic circuit 200 includes an eligibility trace generation circuit 210 coupled to a synapse tuning circuit 230. As a general overview, the eligibility trace generation circuit 210 receives context and variability signals 212, 214 respectively and operates to generate a delayed-onset, self-resetting signal (which may be referred to herein as an “eligibility trace signal” or more simply an “eligibility trace”). The eligibility trace generation circuit 210 provides the eligibility trace to an input of synapse tuning circuit 230. Synapse tuning circuit 230 also receives the context signal 212 as well as a reward signal 232. When the eligibility trace, context and reward signals all have amplitudes above respective predetermined threshold values, the synapse tuning circuit 230 provides an output signal 250. If a reward signal 232 is input during a time period in which an amplitude of the eligibility trace and the context signals are above respective threshold values, the synapse 230 is strengthened by the reward signal 232.

On the other hand, any reward signal 232 that arrives while the eligibility trace is zero or has an amplitude below a threshold value the reward signal 232 is unable to strengthen the synaptic connection.

Context signals 212 can be, for example, one or more timing signals disclosing the promptness or arrival of a signal provided from a context signal generator 202. For example, a higher vocal center (HVC) of a brain of a bird having performed a song would produce a context signal disclosing the song has been or is being performed. Thus, in this songbird example, the context signal generator corresponds to the HVC of a brain of a bird having performed a song. The context signal generator 202 transmits or otherwise provides one or more context signals 212 to the eligibility trace generation circuit 210 and the synapse tuning circuit 230.

The variability signals 214 can be, for example, one or more variations in a signal) provided from a variability signal generator 204. For example, in the songbird example, a lateral magnocellular nucleus of the nidopallium (LMAN) of a brain of a bird having performed a song would produce a variability signal disclosing the gradient of the song if the bird had sung the song correctly. Thus, in this songbird example, variability signal generator corresponds the lateral magnocellular nucleus of the nidopallium (LMAN) of a brain of a bird having performed a song. The variability signal generator 204 transmits or otherwise provides one or more variability signals 214 to the eligibility trace generation circuit 210. The eligibility trace generation circuit 210 generates the eligibility trace at the coincidence of the context signals 212 and variability signals 214.

The eligibility trace generation circuit 210 includes a first electrochemical ionic synapse (EIS) 220. In embodiments, volatile EIS 220 comprises a field effect transistor (FET) having a source terminal 222 (or more simply a “source”) coupled to a first reference potential, which in this example embodiment is illustrated as ground; a drain terminal (or more simply a “drain”) 224 coupled to a second reference potential, which in this example embodiment is illustrated as V_{REF1}; and a gate terminal (or more simply a “gate”) 226 coupled to receive context and variability signals 212, 214 respectively. The reference voltage V_{ref1} 218a can, for example, be provided from a reference voltage source 206a that transmits or otherwise provides the reference voltage V_{ref1} 218a to the eligibility trace generation circuit 210.

The eligibility trace generation circuit 210 further includes a second FET 216 having a source terminal coupled to a reference voltage V_{ref2} 218b, a gate terminal coupled to the drain terminal 224 of EIS 220, and a drain terminal coupled to an input of synapse tuning circuit 230. The reference voltage V_{ref2} 218b can be, for example, provided from a reference voltage source 206b. The reference voltage source 206b transmits or otherwise provides the reference voltage V_{ref2} 218b to the eligibility trace generation circuit 210.

In response to a non-zero electrical stimulus applied to the first EIS 220, the first EIS 220 operates in a volatile operation mode to generate the eligibility trace signal. Thus, first EIS 220 is sometimes referred to herein as volatile EIS 220.

When context signals 212 and variability signals 214 have amplitudes above respective threshold values and are transmitted or otherwise provided to gate 226 of volatile EIS 220, volatile EIS 220 provides an eligibility trace signal at signal path 201 to gate.

The eligibility trace generation circuit 210 provides the eligibility trace via signal path 201 and FET 216 to an input of the synapse tuning circuit 230. The synapse tuning circuit 230 also receives the context signal 212 as well as a reward signal 232. The reward signals 232 can be, for example, one or more signals provided from a reward signal source 208. The reward signal source 208 may be external to the supporting circuit (i.e., the circuitry disclosed in FIG. 1A coupled to hybrid ionic-electronic circuit 122). In the songbird example, the reward signal may be generated external to a brain of a bird having performed a song and provided or transmitted to the brain. The reward signal source 208 transmits or otherwise provides one or more reward signals 232 to the synapse tuning circuit 230.

The synapse tuning circuit 230 includes a second EIS 240. EIS 240 may be provided as a FET having a gate terminal (or more simply, a “gate”) 242, a source terminal (or more simply, a “source”) 244, and a drain terminal (or more simply, a “drain”) 246. In response to a non-zero electrical stimulus applied to a terminal of the second EIS 240, the second EIS 240 operates in a non-volatile operation mode. Thus, EIS 240 is sometimes referred to herein as nonvolatile EIS 240.

A conductance of nonvolatile EIS 240 produces and controls a strength (e.g. an amplitude of a current or voltage) of an output reward signal 250 (which may sometimes be referred to herein simply “output signal 250” or even more simply as “output 250”) of the nonvolatile EIS 240. The non-zero electrical stimulus for nonvolatile EIS 240 may be provided from one or more of: the eligibility trace 201; one or more reward signals 232; and/or one or more context signals 212.

The eligibility trace signal and reward signal 232 are used as the driving signals (e.g., driving voltages) for the nonvolatile EIS 240. In the example embodiment of FIG. 2, the eligibility trace and the reward signals 232 are applied to gate 242 of a FET which functions as the nonvolatile EIS 240. When eligibility trace and the reward signals have amplitudes above respective threshold value, the eligibility trace and the reward signals alter the conductivity between the source 244 and drain 246 of nonvolatile EIS 240. As disclosed above, nonvolatile EIS 240 thus uses the eligibility trace and the reward signals to control the conductance of nonvolatile EIS 240 and in turn control the synaptic strength of electrochemical synapse 230.

If the reward signals 232 are input during an eligibility time window (i.e., before an amplitude of the eligibility trace falls below a threshold level sufficient to bias FET 240 into it's conducting state or the eligibility trace terminates or dies off), the eligibility trace signal (e.g., eligibility trace voltage) is applied on the nonvolatile second EIS 240 producing an output reward signal 250. In this case (i.e., when reward signal 232 is applied while an amplitude of the eligibility trace is above a threshold level), the synapse is strengthened by the reward signal 232.

On the other hand, any reward signal 232 that arrives while the eligibility trace is zero or has an amplitude below a threshold level (thereby indicating there is no coincidence between the context and variability signals) the reward signal 232 is unable to strengthen the synaptic connection.

The conductance of volatile first EIS 220 is “read out” (i.e., the conductance of volatile first EIS 220 is characterized by converting it to a voltage or current signal). As noted above, the non-zero electrical stimulus for volatile EIS 220 may be provided from one or more context signals 212 or one or more variability signals 214. When both context signals 212 and variability signals 214 fire (i.e., when both context signals 212 and variability signals 214 are provided to the eligibility trace generation circuit 210 (and in particular to the volatile first EIS 220) having sufficient strength—e.g., sufficient voltage levels or amplitudes above a predetermined threshold sufficient to bias the FET 220 into its conducting state), the eligibility trace is generated at signal path 201.

After the coincidence of context signals 212 and variability signals 214 is detected (i.e. when it is determined that both the context and variability signals have sufficient strength—i.e., having sufficient voltage levels or amplitudes above a predetermined threshold sufficient to bias the FET 220 into its conducting state), the eligibility trace transient starts to rise. After the eligibility trace signal reaches its highest amplitude (i.e., delayed onset) the eligibility trace then gradually relaxes back to zero (i.e., the eligibility trace signal is self-resetting). The specific timescale and functional form of the eligibility trace depends on the time window of the reward feedback of the specific task, as the strength of the trace ensures that the rewards that arrive during the optimal timing window strengthen the synaptic connection, while those that come in early or late (i.e., either of the context signals 212 or variability signals 214 are too early or late) have a diminishing effect. Reward signals that arrive too late (i.e., after the optimal timing window) do not strengthen the synaptic connection, as there may be no causal relation.

Accordingly, when the input signal (which is formed from the context and variability signals 212, 214), is active (i.e., when both the context and variability signals have sufficient strength), it increases the conductance of the volatile first EIS 220, away from the starting voltage value. When the input signal is not active, meaning only one of the context signals 212 and variability signals 214 is present at an amplitude above a threshold value, the voltage is Vᵣₑₛₜ, and the conductance of the volatile EIS 220 stays at a fixed starting value, determined by Vᵣₑₛₜ.

In an embodiment, there may be a time delay between when the voltage input signal goes back to Vᵣₑₛₜ and when the conductance starts to trend back towards the initial value. Accordingly, the effect of the active signal could last longer than the active signal itself, with a prolonged effect after the input voltage returns to Vᵣₑₛₜ. This delay is caused by the active input voltage waveform, which drives the volatile first EIS 220 away from equilibrium, as the intrinsic electrochemical processes, such as diffusion and charge accumulations, are not instantaneous. The delay can be tuned by factors such as Vᵣₑₛₜ, the active input signal waveform, and the materials and geometry of the EIS devices.

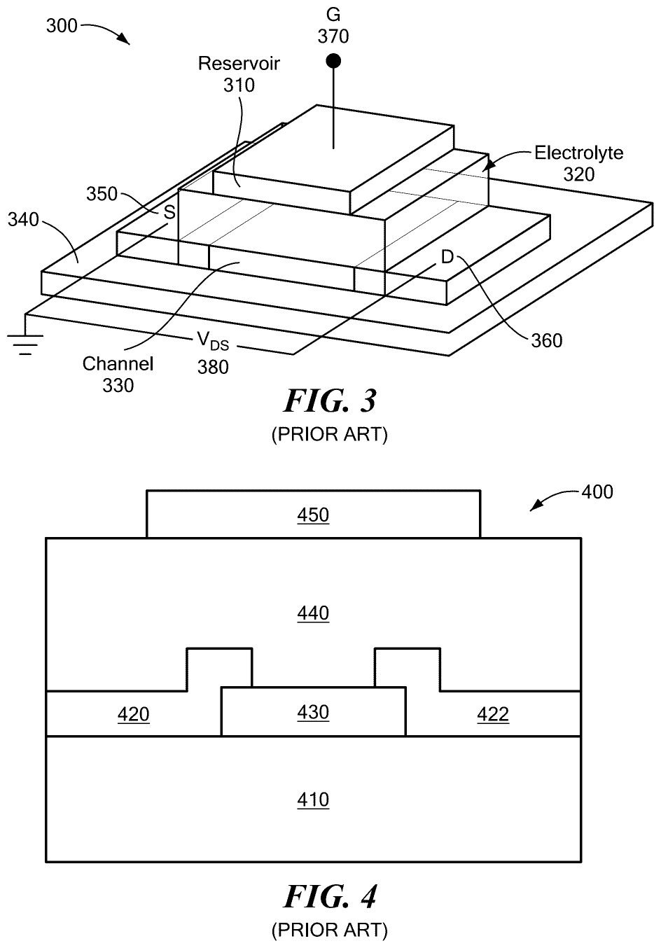

In an embodiment, the channel of volatile-EIS (which will be discussed in reference to channel 330 in FIG. 3) and the serial resistor 228 form a voltage divider. In an embodiment, the resistor 228 has a resistance value of about 4.2 MΩ (+/−0.1 MΩ) and is coupled (here, serially coupled) between a reference voltage V_{ref1} 218a and the drain terminal 224. In an example embodiment, the context in and variability in signals 212, 214 may be 3 V, 500 us pulses, and the resulting eligibility trace may be a 10 V pulse with duration of 30 ms. A resistor 236 having a resistance value in the range of about 1 MΩ may be coupled between the reward signal 232 and a node 238 located between the drain terminal 224 of first EIS 220 and the gate terminal 242 of the second EIS 240.

The output reward signal 250 of the second EIS 240 can be configured to implement reinforcement learning at the level of neural circuits. The volatile first EIS 220 generates a dynamic signal trace (such as an eligibility trace) using one EIS and a limited number of components. The EIS described herein may be also referred to as an electrochemical random-access memory (ECRAM), it should be understood that the EIS may comprise an ECRAM. The generated signal from the eligibility trace generation circuit 210 is suitable as an eligibility trace that may be relevant to different reinforcement learning mechanisms and can also be used beyond the circuit 200 to implement complex dynamics and learning rules. In contrast to a non-volatile programmable resistor or implementing a signal trace using standard complementary metal-oxide-semiconductor (CMOS) logic circuits, the eligibility trace generation circuit 210 uses less area and energy by utilizing the intrinsic dynamics of a volatile first EIS 220 to carry out computations. Through the hybrid ionic-electronic circuit 200, the synapse-like EIS in volatile mode is used to implement coincidence detection, time-coordination, and synapse weight updates on the nonvolatile EIS.

FIG. 3 illustrates a prior art EIS device 300 (such as first EIS 220 or second EIS 240 of FIG. 2) suitable for use in a hybrid ionic-electronic circuit (such as the circuit 200 of FIG. 2). The EIS 300 includes an ion reservoir 310, an electrolyte 320, and a channel 330 formed on or disposed over a substrate 340. The channel 330 is disposed over (here directly on) the substrate 340. The channel 330 is provided from one or more materials with a tunable electronic conductivity that is determined by an ion concentration. A source 350 is disposed over (here directly on) a first end of the channel 330 and a drain 360 is disposed over (here directly on) a second opposing end of the channel 330. The electrolyte 320 is disposed over (here directly on) the channel 330, the source 350, and the drain 360. The ion reservoir 310 disposed over (here directly on) the electrolyte 320. In response to a non-zero electrical stimulus one or more ions are released from the ion reservoir 310. A gate 370 is disposed over (here directly on) the ion reservoir 310.

The operations of EIS 300 is based on shuffling of dopants across active device layers that control the conductance of the channel 330 in a three-terminal configuration. Three electrodes 350, 360, 370 are placed as disclosed in FIG. 3 for the operation of the EIS 300. The voltage conductance of the channel 330 can be read out by measuring the current from a small (i.e., 0.1 V) voltage (V_{DS}) 380 applied across the source 350 and drain 360. The voltage (V_{DS}) 380 may refer to a small voltage, meaning one that is selected in order to minimize the effect of this voltage on the conductance of the channel. Thus, the small voltage (V_{DS}) 380 could be lower or higher depending on the EIS device.

For a cation-based EIS, where cations are the mobile ions in the electrolyte, when a gate voltage (V_{G}) that is higher than the open-circuit potential (VOCP) is applied, the cations are extracted from the ion reservoir 310, migrate through the electrolyte 320, and intercalate into the channel 330. Meanwhile, electrons take the outer circuit from the ion reservoir 310 to the channel 330. The cation and electron insertion into the channel 330 causes a change, often an increase, in electronic conductivity of the semiconducting material of choice for the channel 330. This change can lead to potentiation, strengthening of the synapse. Conversely, a V_{G} lower than VOCP reverses the process. The resulting change in conductance of the channel 330 is a non-volatile EIS (such as the EIS 240 in FIG. 2), where the gate circuit is open after each programming pulse.

In a non-volatile EIS (such as the EIS 240 in FIG. 2), the conductance will eventually relax back to a fixed conductance value set by the resting voltage. A long-term self-resetting behavior can be utilized as a controlled forgetting mechanism. In an embodiment, the EIS layers may be designed such that the response is slow at low gate voltage (meaning a voltage of 0 volts), to enable a long retention time. Response times are defined relative to the timescale of the neural dynamics that the circuit aims to emulate. For the EIS device, the response at low gate voltage (meaning a voltage of 0 volts), could be more than 10⁹ times slower than at high voltage (meaning a voltage of 10 volts). In an embodiment, another transistor may be positioned at the gate of the non-volatile EIS to open the gate of the EIS. The gate of nonvolatile EIS can be set to open when resting, enabling the non-volatile EIS to operate with longer retention.

In embodiments, the non-volatile EIS may not be perfectly non-volatile due to leakage or due to external electronic paths between the gate and the channel. Thus, the conductance of the non-volatile EIS may relax towards an equilibrium state over extended (i.e., longer) timescales. For the hybrid ionic-electronic circuit (such as the circuit 200 of FIG. 2) to function, the non-volatile EIS does not need to exhibit perfect non-volatility. The non-volatile EIS can have a retention timescale longer than the volatile EIS. The term “volatile operation mode” means that the synapse resets back towards its initial state with a timescale comparable to the desirable timescale of the eligibility trace.

In a volatile EIS (such as the first EIS 220 in FIG. 2), an eligibility trace may be generated at the coincidence of the context and the variability signals. If the EIS 300 were to be operated in a volatile operation mode, the conductance of the EIS 300 generates a time-varying and self-resetting signal that can be read out and utilized in a variety of different ways.

The response rate of a EIS in a volatile mode is dependent on the voltage applied. The strongly non-linear, exponential dependence of the volatile EIS response rate is used to detect coincidence based on the voltage applied from the context signals and variability signals. Strong non-linear dependence refers to the EIS response, meaning the conductance change, from half of a full gate voltage is negligible (less than 1/100) when compared to the response to the full gate. The intrinsic non-linearity arises from the exponential dependence of ion transport and interface charge transfer reactions on the applied potential.

In an embodiment, the conductance of the EIS 300 can be read out by measuring the current flowing through the channel 330 with a fixed bias voltage across the source 350 and the drain 360. In an embodiment, the conductance of a volatile EIS 300 can be read out by using a voltage divider circuit to convert it to a voltage signal, which is amplified by transistors for driving other parts of the circuit (e.g., as shown in the hybrid ionic-electronic circuit 200 in FIG. 2). In an embodiment, the EIS 300 further includes a voltage divider circuit disposed over (here directly on) the gate 370 to form a coincidence detector (AND-gate). By forming a voltage divider circuit on the gate 370, a coincidence detector (AND-gate) can be implemented to trigger the signal generation only when both the context-in and the variability-in signals are on at the same time. The gate input impedance is such that the gate voltage (V_{G}) of the volatile EIS is determined by a voltage divider (two equal resistors) formed between the context and variability signal and can be calculated as V_{G}=(V_{context}+V_{variability})/2.

The high gate voltage from a coincidence of context signals and variability signals triggers the potentiation of the volatile EIS. High gate voltage here refers a voltage level that is sufficient to trigger a much stronger change (e.g., greater than a change of 100×) than the voltage that is received when only one of the two signals (meaning one of V_{context} and V_{variability}) fires. The volatile EIS has an intrinsic onset delay due to the interfacial ionic capacitances and ion redistributions in the channel. After the volatile EIS is potentiated, it relaxes back to a reference state over time. This is achieved by keeping a chosen rest potential on the device, allowing for the controllable decay of the eligibility signal. The rest potential controls the speed that the conductance reduces back. Thus, the rest potential may be chosen to match the desired timescale of the eligibility trace. In a volatile EIS (such as the volatile first EIS 220 in FIG. 2), if the gate 370 is connected to the initial VOCP after the application of potentiation/depression pulses, the ion concentrations in each layer 310, 320, 330 are driven towards their initial values over time. As a result, the conductance of the EIS will self-reset back to the initial value.

The voltage at the drain 360 depends on the conductance of the EIS channel 330. The conductance of a volatile EIS (such as EIS 220 of FIG. 2) is connected to a voltage using a transistor connected to one or more proper reference voltages and serial resistors. In an embodiment, the source 350 comprises chromium (Cr) or gold (Au) and the drain 360 comprises Cr or Au. In an embodiment, the gate 370 comprises palladium (Pd), having a width of about 15 nm (+/−2 nm).

A wide range of ions, materials and geometries may be used to form EIS 300. In an embodiment, the substrate 340 comprises any form of suitable semiconductor material. The ion reservoir 310 may be formed from materials that can store and release ions. The ion reservoir 310 may include: Pd and Pd alloys; Mg; WOₓ; NbOₓ; VOₓ; MoOₓ; TiOₓ; TaOₓ; CrOₓ; NiOₓ; poly(3,4-ethylenedioxythiophene) polystyrene sulfonate (PEDOT:PSS); Li₁₋ₓCoO₂; LiTiO₂; MXenes; Pr₁₋ₓCaₓMnO₃ (PCMO); and/or metal-based prussian blue analogues (PBAs). It should be appreciated, that the ion reservoir 310 may include all anode and cathode materials described herein, including but not limited to, anode and cathode materials for H, Li, Na, Ca, Mg, Al, K, O batteries.

The electrolyte 320 conducts ions, such as H⁺, Li⁺, Na⁺, K⁺, Ca²⁺, Mg²⁺, O²⁻. The electrolyte 320 may be formed from materials that are electronically insulating and conduct ions at and near room temperature (25° C.). The electrolyte 320 may include: yttria-stabilized zirconia (YSZ); HfO₂; phosphosilicate glass (PSG); ZrO₂; CeO₂ with optional doping; MgO; Al₂O₃; TiO₂; Ta₂O₅; Y₂O₃; Nafion; lithium phosphorous oxynitride (LiPON); Li₃PO₄; ionic liquids; aqueous solutions; body fluids such as blood; and/or brain fluid. It should be appreciated, that the electrolyte 320 may include all electrolyte materials described herein, including but not limited to, electrolyte materials for H, Li, Na, Ca, Mg, Al, K, O batteries. In an embodiment, the electrolyte comprises about 7 nm (+/−1 nm) to about 21 nm (+/−1 nm) of yttria-stabilized zirconia (YSZ).

The channel 330 comprises materials with tunable electronic conductivity that are defined by their ion concentration. The channel 330 may be formed from materials with electronic conductivity modulated by ion intercalation. The channel 330 may include: WOₓ; NbOₓ; VOₓ; MoOₓ; TiOₓ; TaOₓ; CrOₓ; NiOₓ; poly(3,4-ethylenedioxythiophene) polystyrene sulfonate (PEDOT:PSS); Li₁₋ₓCoO₂; LiTiO₂; MXenes; Pr₁₋ₓCaₓMnO₃ (PCMO); and/or metal-based prussian blue analogues (PBAs). It should be appreciated, that the channel 330 may include all anode and cathode materials described herein, including but not limited to, anode and cathode materials for H, Li, Na, Ca, Mg, Al, K, O batteries. In an embodiment, the channel 330 includes about 10 nm (+/−1 nm) of tungsten trioxide (WO₃), a width of about 3 um (+/−1 um) to about 20 um (+/−1 um), and a length of about 3 um (+/−1 um) to about 20 um (+/−1 um).

FIG. 4 is a cross-sectional side view of a prior art EIS 400 for a hybrid ionic-electronic circuit (such as the circuit 200 of FIG. 2). A channel 430 is disposed over (here directly on) a substrate 410, with a source 420 and a drain 422 disposed over (here directly on) the substrate 410 on opposing ends of the channel 430. An electrolyte 440 is disposed over (here directly on) the channel 430, source 420, and drain 422. A gate 450 is disposed over (here directly on) the electrolyte 440.

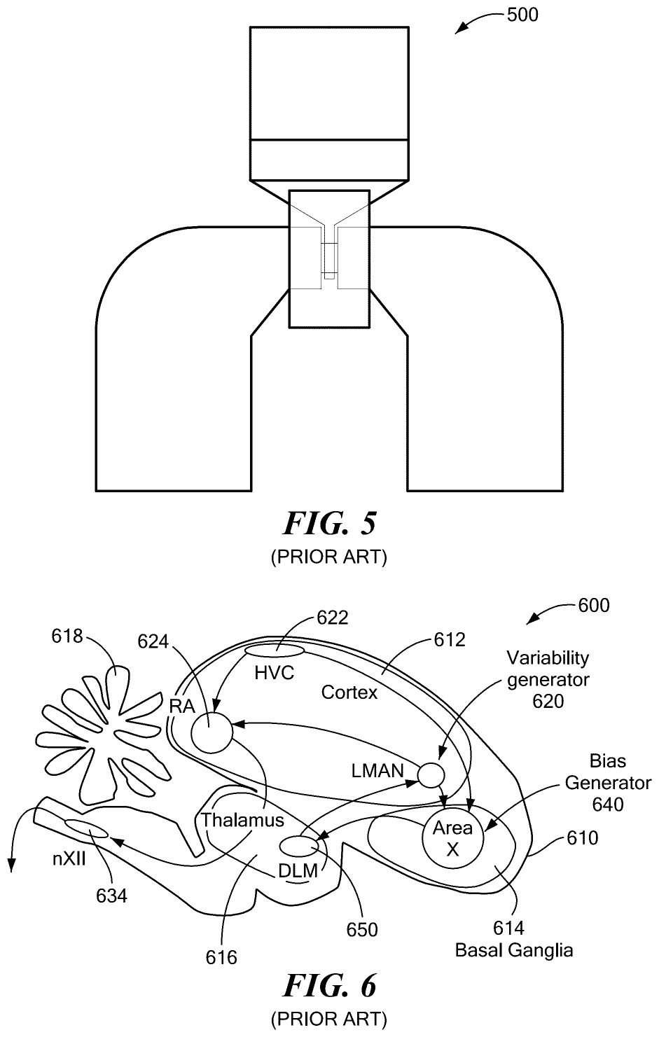

FIG. 5 is a top view of a prior art EIS 500 for a hybrid ionic-electronic circuit. The microscope image of an EIS device 500, that may be similar to EIS 400 of FIG. 4.

FIG. 6 is a cross sectional side view of a schematic diagram 600 of a prior art brain of a songbird, illustrating song-related neural circuits and connections. A cerebellum 618 is disposed next to a cerebrum 610. A cortex 612, basal ganglia 614, thalamus 616, and brainstem (nXII) are disposed adjacent to one another in the cerebrum 610. The cortex 612, basal ganglia 614, thalamus 616, and brainstem (nXII) 634 are interconnected structures in the songbird forming the motor circuit for song control, enabling the song learning circuit.

In the thalamus 616 is a dorsolateral medial nucleus of the thalamus (DLM) 650. In the cortex 612 is a HVC 622, a LMAN 620, and a robust nucleus of the arcopallium (RA) 624. In the basal ganglia 614 is area X 640. The LMAN 620 is the variability generator and area X 640 is the bias generator.

Through a process of self-listening and listening to other songbirds, songbirds refine their vocalizations until they can accurately reproduce the tutor song once they reach adulthood. The three-factor learning theory that explains a type of learning called “node-perturbation.” This theory suggests that this learning mechanism serves as an efficient rule for implementing reinforcement learning at the level of neural circuits. In this framework, LMAN 620 fluctuations become biased in a direction that points “up” at the gradient of song performance in the space of the motor control parameters in the RA 624, at each moment in the song. More specifically, the gradient is computed in the basal ganglia 614 circuit formed by area X 640 by combining known inputs to this region: timing (context) signals from HVC 622; variability signals generated from LMAN 620; and performance evaluation signals from a dopaminergic brain region ventral tegmental area (VTA).

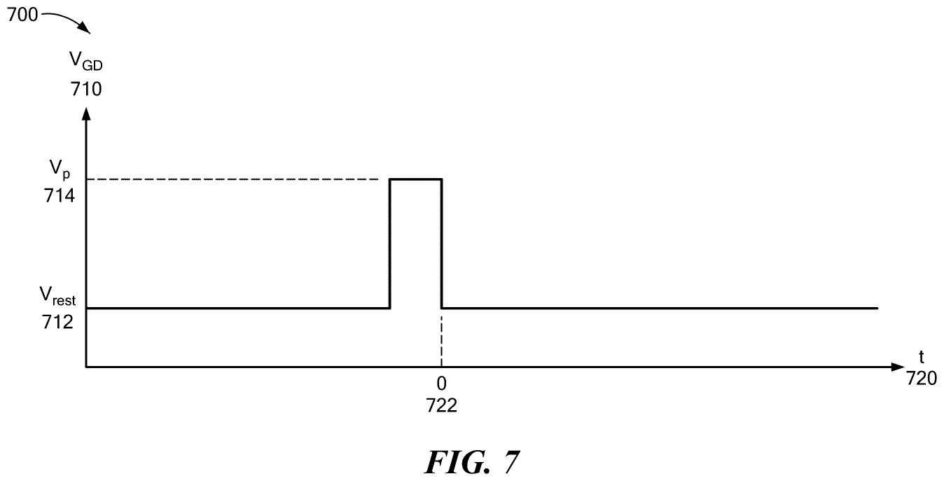

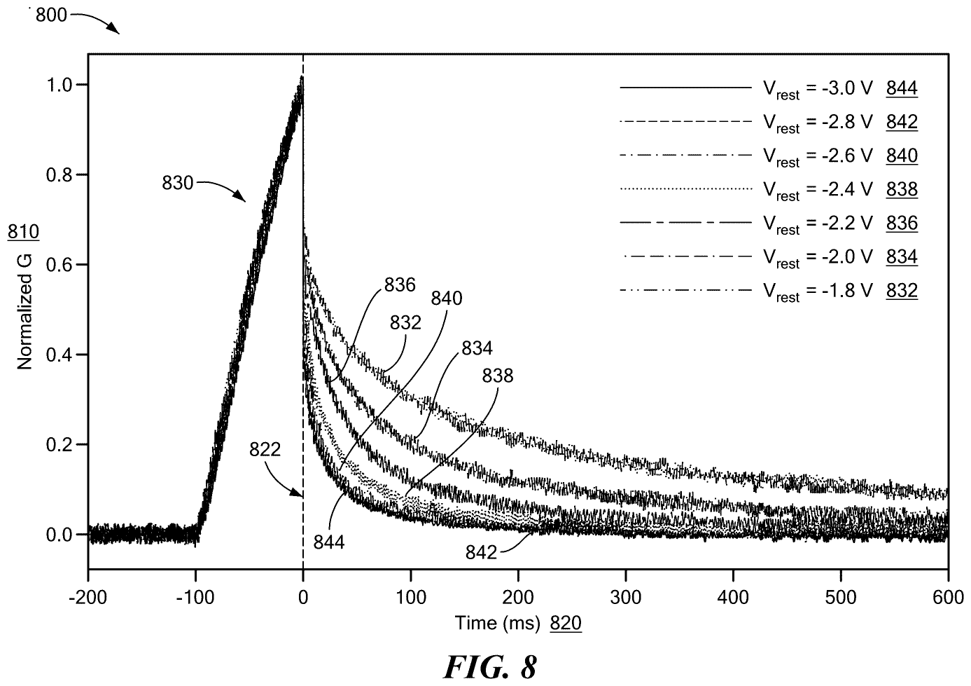

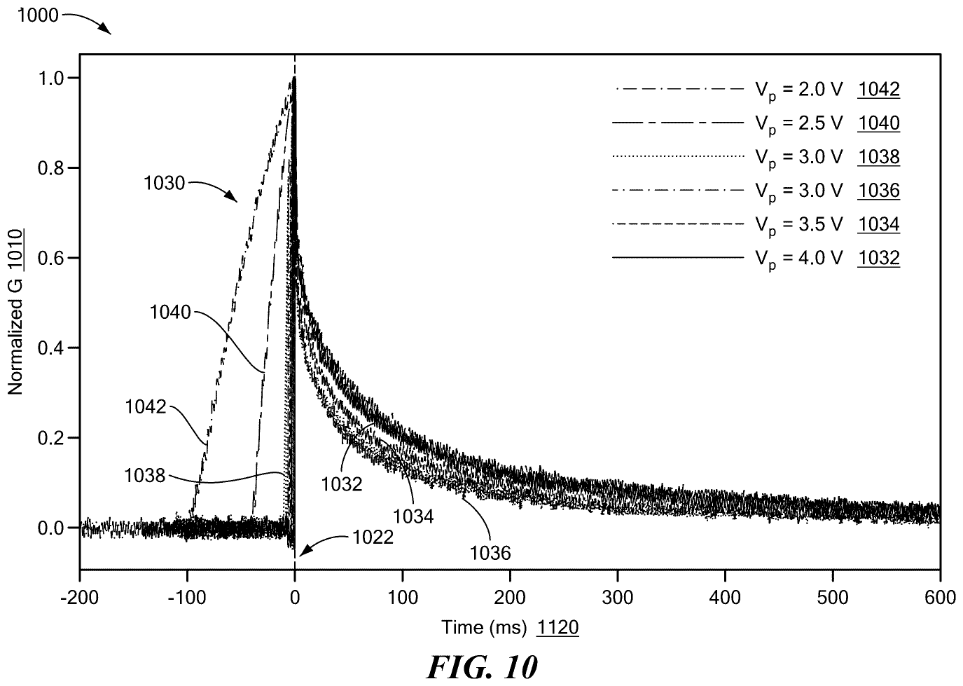

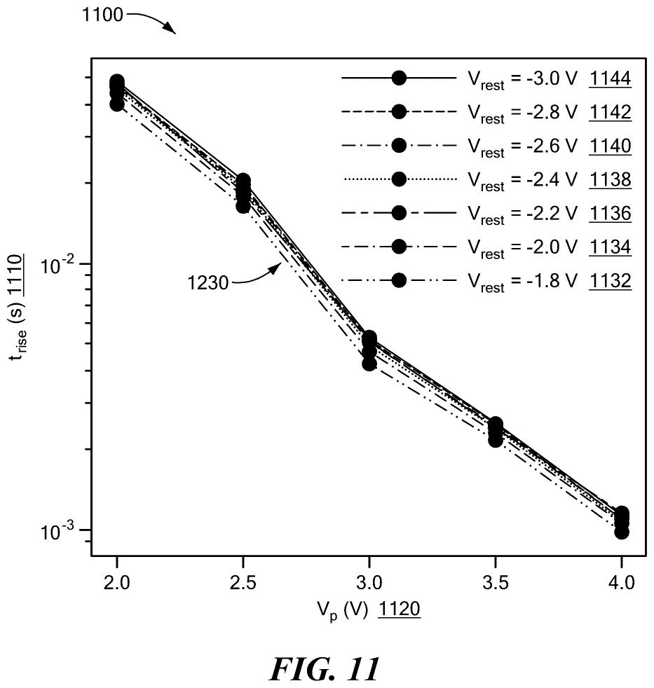

FIG. 7 is a graph 700 of voltage (V_{GD}) 710 vs. time 720, disclosing the signal waveform on a gate of a volatile EIS. Vᵣₑₛₜ, given in point 712, is the resting voltage and may be varied (Vᵣₑₛₜ is varied in FIGS. 8 and 11) to illustrate how Vᵣₑₛₜ has little to no effect on the rising time. Vₚ is the voltage level for the voltage pulse, which is given at point 714. Vₚ is selected to be positive enough to be able to drive the conductance up enough to be clearly measurable (i.e., greater than 1 ns). Vₚ is varied (in FIGS. 7 and 10) to study and demonstrate the effect of Vₚ on the timescale taken for the conductance to rise. In FIGS. 7 and 10, varying the Vₚ illustrates how a higher Vₚ results in a faster conductance rise for the volatile EIS. FIG. 7 illustrates the waveform shape applied to the gate (V_{GD}). The time 720 is referenced to the falling edge of the pulse (t=0 at a point 722 at the falling edge).

FIG. 8 is a graph 800 of normalized conductance (G) 810 vs. time (ms) 820, with t=0 given by a line 822. FIG. 8 illustrates a conductance trace (given generally as conductance traces 830) when a 100 ms pulse is applied to the gate of a volatile EIS, with Vₚ=2 V. Vᵣₑₛₜ ranges from −1.8 V to −3.0 V, with a first line 832 disclosing Vᵣₑₛₜ=−1.8 V; a second line 834 disclosing Vᵣₑₛₜ=−2.0 V; a third line 836 disclosing Vᵣₑₛₜ=−2.2 V; a fourth line 838 disclosing Vᵣₑₛₜ=−2.4 V; a fifth line 840 disclosing Vᵣₑₛₜ=−2.6 V; a sixth line 842 disclosing Vᵣₑₛₜ=−2.8 V; and a seventh line 844 disclosing Vᵣₑₛₜ=−3.0 V. Varying Vᵣₑₛₜ illustrates how a more negative Vᵣₑₛₜ provides an increased (i.e., faster) self-reset. Each of the conductance traces 830 first increase with the pulse on and then decrease after the pulse is off, which enables the delay and self-reset of the eligibility trace. With an increase in negative Vᵣₑₛₜ, the speed of self-reset increases faster.

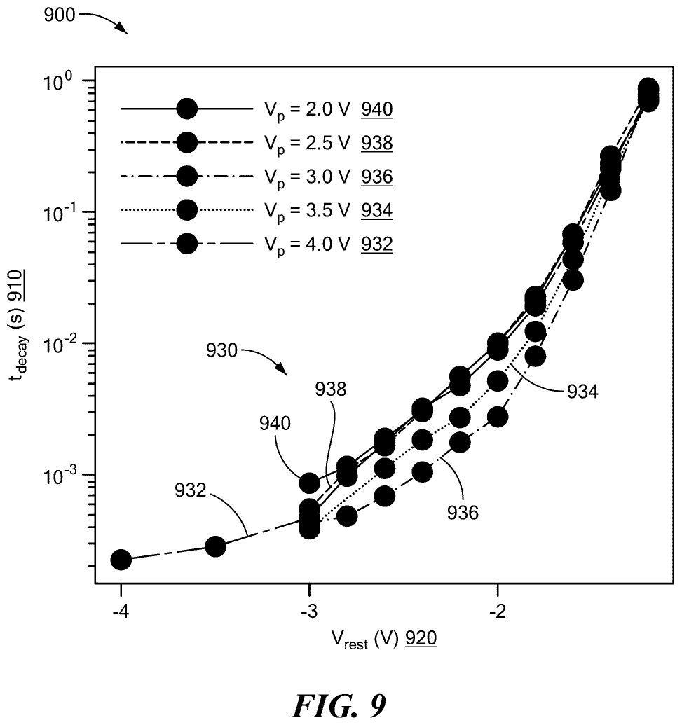

FIG. 9 is a graph 900 of time decay (t_{decay}) (s) 910 vs. Vᵣₑₛₜ (V) 920, disclosing the time it takes for the conductance (given generally as conductance lines 930) to reduce to 50% from its highest value (t_{decay}). Vₚ ranges from 4.0 V to 2.0 V, with a first line 932 disclosing Vₚ=4.0 V; a second line 934 disclosing Vₚ=3.5 V; a third line 936 disclosing Vₚ=3.0 V; a fourth line 938 disclosing Vₚ=2.5 V; and a fifth line 940 disclosing Vₚ=2.0 V.

FIG. 9 depicts the timescale of the self-reset process by t_{decay}, which is the time it takes for the conductance to reduce to 50% from its highest value. The highest value is determined experimentally as the highest conductance of each conductance trace. The tᵣᵢₛₑ and t_{decay} characterize the speed of the rise and decay of the conductance. The use of 50% was chosen in order to characterize each case quantitatively. FIG. 9 illustrates that the timescale of self-reset can be tuned by more than 1000-times by changing the voltage, ranging from seconds to submilliseconds.

FIG. 10 is a graph 1000 of normalized conductance (G) 1010 vs. time (ms) 1020, with t=0 given by a line 1022. FIG. 11 illustrates a conductance trace (given generally as conductance traces 1030) when a voltage pulse is applied to the gate of a volatile EIS, with Vᵣₑₛₜ=−3 V. Vₚ ranging from 2 V to 4 V, with a first line 1032 disclosing Vₚ=4.0 V; a second line 1034 disclosing Vₚ=3.5 V; a third line 1036 disclosing Vₚ=3.0 V; a fourth line 1038 disclosing Vₚ=3.0 V; a fifth line 1040 disclosing Vₚ=2.5 V; and a sixth line 1042 disclosing Vₚ=2.0 V. FIG. 10 discloses the change in the conductance trace when the gate receives a pulse waveform with the same Vᵣₑₛₜ and different Vₚ values. As illustrated by FIG. 10, the conductance rises faster with higher Vₚ.

FIG. 11 is a graph 1100 of time (tᵣᵢₛₑ) (s) 1110 vs. Vₚ (V) 1120, disclosing the time it takes for the conductance (given generally as conductance lines 1130) to rise to 50% of the highest level (tᵣᵢₛₑ). Vᵣₑₛₜ ranges from −3.0 V to −1.8 V, with a first line 1132 disclosing Vᵣₑₛₜ=−1.8 V; a second line 1134 disclosing Vᵣₑₛₜ=−2.0 V; a third line 1136 disclosing Vᵣₑₛₜ=−2.2 V; a fourth line 1138 disclosing Vᵣₑₛₜ=−2.4 V; a fifth line 1140 disclosing Vᵣₑₛₜ=−2.6 V; a sixth line 1142 disclosing Vᵣₑₛₜ=−2.8 V; and a seventh line 1144 disclosing Vᵣₑₛₜ=−3.0 V. Varying Vᵣₑₛₜ illustrates the increasing (i.e., rising) speed. The conductance rises faster with higher Vₚ, as illustrated by FIG. 11 and the time it takes for the conductance to rise to 50% of the highest level (tᵣᵢₛₑ). This timescale sets the delay time in the generated eligibility trace and can be modulated from tens of milliseconds down to sub milliseconds.

The shape and timescales of the eligibility trace can be tuned by the choice of the context and variability signals, allowing the same device and local circuit to implement learning rules with diverse eligibility traces. FIGS. 7-11 illustrate the tunability by feeding a Vₚ with a Vᵣₑₛₜ to the V_{GD} of the volatile EIS and the effect of Vₚ and Vᵣₑₛₜ on its conductance change over time. The voltage pulse waveform on the gate can be generated by sending context and variability signals that have the same waveform shape. FIGS. 7-11 utilized a volatile EIS consists of a 10 nm WO₃ channel, 10 nm thick phosphosilicate glass (PSG) electrolyte and a 10 nm Pd top gate. During the testing that resulted in the graphs disclosed in FIGS. 7-11, the conductance of the volatile EIS channel was monitored before, during, and after the pulse. The experiment was carried out in 3% H₂ gas mixed with argon (Ar).

In addition to voltage waveforms, the shape and timescales of the conductance trace can be tuned by device configurations and material parameters, including: the thickness of electrolyte layer; the ionic conductivity of the electrolyte; the interfacial ionic capacitances; and the ion diffusivity of the intercalated ions in the channel. The eligibility trace is generated from the conductance trace by a voltage divider and a transistor, so it can be further tuned by the choice of the resistances of the voltage divider, the transistor properties, and the voltage references (V_{REF1} and V_{REF2}).

When both the variability signal and the context signal are high at the same time, the cumulative gate voltage sent to the gate of the volatile EIS is high, which induces a strong response. In contrast, when the variability and the context signal do not overlap, the V_{G} pulses are lower (about half of the input pulses), so the response is negligibly lower, and the eligibility remains as zero. With the reward signal turned on, the resulting signal at the gate of the nonvolatile EIS is consistent with the shape of the eligibility trace function that may be used for reinforcement learning in songbirds.

The disclosed hybrid ionic-electronic hardware architecture emulates the biological learning of a complex vocal behavior in the songbird. By using the disclosed electrochemical synapses as building blocks and harnessing their intrinsic ion dynamics, the bio-plausible learning rule can be implemented with a small footprint, meaning containing one transistor and one electrochemical synapse as active components. Thus resulting in potentially a 10,000 times reduction in energy consumption compared to conventional digital CMOS counterparts.

The disclosed circuit can be applied in energy efficient hardware implementations of reinforcement learning, paves the path to emulate rich nonlinear dynamics involved in neural systems and brain functions in a bio-realistic and energy-efficient manner for intelligent edge computing devices, miniaturized controller circuit. Further, it can potentially establish an artificial intelligence hardware platform with complex biophysical behaviors acquired through trial-and-error learning. Additionally, it may guide the design of brain-guided and extremely energy-efficient hardware in contexts such as speech, language learning and mobility.

Mechanism for the reduction of non-volatile synapse conductance (i.e., depression) can be implemented for better emulation of the behavior in biological systems and enabling additional flexibility. One approach is to implement forgetting over time, where the conductance decreases over time when there is no potentiation event. This can be achieved by including an EIS that is not perfectly non-volatile, such that it loses its conductance modulation overtime. The conductance loss timescale may be controlled by engineering the electronic conductivity of the electrolyte or by connecting an external resistor with a controlled resistance between the gate and ground. Alternatively, the controlled conductance decrease could be achieved by tuning the resting voltage of the reward signal. Alternatively, another depression mechanism that may be utilized herein is to allow for negative reward signals. Negative reward signals have the opposite sign to the potentiation voltage and represent penalty. The non-volatile EIS is depressed when the negative reward signal arrives in the eligible window started by the coincidence of context and reward signals.

Although reference is made herein to particular materials, it is appreciated that other materials having similar functional and/or structural properties may be substituted where appropriate, and that a person having ordinary skill in the art would understand how to select such materials and incorporate them into embodiments of the concepts, techniques, and structures set forth herein without deviating from the scope of those teachings.

Various embodiments of the concepts, systems, devices, structures and techniques sought to be protected are described herein with reference to the related drawings. Alternative embodiments can be devised without departing from the scope of the concepts, systems, devices, structures and techniques described herein. It is noted that various connections and positional relationships (e.g., over, below, adjacent, etc.) are set forth between elements in the following description and in the drawings. These connections and/or positional relationships, unless specified otherwise, can be direct or indirect, and the described concepts, systems, devices, structures and techniques are not intended to be limiting in this respect. Accordingly, a coupling of entities can refer to either a direct or an indirect coupling, and a positional relationship between entities can be a direct or indirect positional relationship.

As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s). The following definitions and abbreviations are to be used for the interpretation of the claims and the specification. As used herein, the terms “comprises,” “comprising, “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance, or illustration. Any embodiment or design described herein as “exemplary” is not necessarily to be construed as preferred or advantageous over other embodiments or designs. The terms “one or more” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment, “an embodiment,” “an example embodiment,” etc., indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal, “top,” “bottom,” and derivatives thereof shall relate to the described structures and methods, as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value In an embodiment, within ±10% of a target value In an embodiment, within ±5% of a target value In an embodiment, and yet within ±2% of a target value In an embodiment. The terms “approximately” and “about” may include the target value. The term “substantially equal” may be used to refer to values that are within ±20% of one another In an embodiment, within ±10% of one another In an embodiment, within ±5% of one another In an embodiment, and yet within ±2% of one another In an embodiment.

The term “substantially” may be used to refer to values that are within ±20% of a comparative measure In an embodiment, within ±10% In an embodiment, within ±5% In an embodiment, and yet within ±2% In an embodiment. For example, a first direction that is “substantially” perpendicular to a second direction may refer to a first direction that is within ±20% of making a 90° angle with the second direction In an embodiment, within ±10% of making a 90° angle with the second direction In an embodiment, within ±5% of making a 90° angle with the second direction In an embodiment, and yet within ±2% of making a 90° angle with the second direction In an embodiment.

It is to be understood that the disclosed subject matter is not limited in its application to the details of construction and to the arrangements of the components set forth in the following description or illustrated in the drawings. The disclosed subject matter is capable of other embodiments and of being practiced and carried out in various ways. Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

What is claimed is:

1. A hybrid electronic-ionic circuit, comprising:
a first electrochemical ionic synapse (EIS), wherein in response to a non-zero electrical stimulus applied to the first EIS, the first EIS operates in a volatile operation mode to generate a delayed-onset self-resetting signal; and
a second EIS, wherein in response to a non-zero electrical stimulus applied to the second EIS, the second EIS operates in a non-volatile operation mode and a conductance of the second EIS controls a strength of an output of the second EIS.

2. The hybrid electronic-ionic circuit of claim 1, wherein the non-zero electrical stimulus for the first EIS comprises one or more of a context signal or a variability signal.

3. The hybrid electronic-ionic circuit of claim 1, wherein the non-zero electrical stimulus for the second EIS comprises one or more of the delayed-onset self-resetting signal, a reward signal, or a context signal.

4. The hybrid electronic-ionic circuit of claim 1, wherein each EIS further comprises: a channel provided from one or more materials with a tunable electronic conductivity that is determined by an ion concentration; an electrolyte disposed over the channel; and an ion reservoir disposed over the electrolyte, wherein in response to a non-zero electrical stimulus one or more ions are released from the ion reservoir.

5. The hybrid electronic-ionic circuit of claim 4, wherein the channel comprises about 10 nm of tungsten trioxide (WO3) and the electrolyte comprises about 7 nm to about 21 nm of yttria-stabilized zirconia (YSZ).

6. The hybrid electronic-ionic circuit of claim 4, wherein each EIS further comprises: a source disposed over a first end of the channel; a drain disposed over a second opposing end of the channel; and a gate disposed over the ion reservoir.

7. The hybrid electronic-ionic circuit of claim 6, wherein the source comprises chromium (Cr) or gold (Au), the drain comprises Cr or Au, and the gate comprises about 15 nm of palladium (Pd).

8. The hybrid electronic-ionic circuit of claim 6, further comprising a voltage divider circuit is disposed over the gate to form a coincidence detector (AND-gate).

9. A circuit, comprising:
one or more hybrid electronic-ionic circuits, wherein the one or more hybrid electronic ionic circuits comprise:
a first electrochemical ionic synapse (EIS), wherein in response to an applied electrical stimulus the first EIS operates in a volatile operation mode to generate a delayed-onset self-resetting signal; and
a second EIS, wherein in response to an applied electrical stimulus the second EIS operates in a non-volatile operation mode and a conductance of the second EIS controls a strength of an output of the second EIS;
one or more context generators configured to generate a context signal, wherein a first context generator is configured to connect to the first EIS and a second context generator is configured to connect to the second EIS;
one or more variability generators configured to generate a variability signal, wherein a first variability generator is configured to connect to the first EIS;
one or more reward signal generators configured to generate a reward signal, wherein a first reward signal generator is configured to connect to the second EIS; and
one or more motor systems, wherein the context signal, variability signal, and output of the second EIS are transmitted to the motor systems.

10. The circuit of claim 9, wherein the applied electrical stimulus for the first EIS comprises one or more of the context signal or the variability signal.

11. The circuit of claim 9, wherein the applied electrical stimulus for the second EIS comprises one or more of the delayed-onset self-resetting signal, the reward signal, or the context signal.

12. The circuit of claim 9, wherein each EIS further comprises: a channel provided from one or more materials with a tunable electronic conductivity that is determined by an ion concentration; an electrolyte disposed over the channel; and an ion reservoir disposed over the electrolyte, wherein in response to a non-zero electrical stimulus one or more ions are released from the ion reservoir.

13. The circuit of claim 12, wherein each EIS further comprises: a source disposed over a first end of the channel; a drain disposed over a second opposing end of the channel; and a gate disposed over the ion reservoir.

14. The circuit of claim 13, wherein a voltage divider circuit is disposed over the gate to form a coincidence detector (AND-gate).

15. A hybrid electronic-ionic circuit, comprising:
an electrochemical ionic synapse (EIS) configured to receive one or more applied electrical stimulus, wherein in response to a coincidence of one or more applied electrical stimulus the EIS operates in a volatile operation mode to generate a time-varying self-resetting signal.

16. The hybrid electronic-ionic circuit of claim 15, wherein the applied electrical stimulus for the EIS comprises one or more of a context signal or a variability signal.

17. The hybrid electronic-ionic circuit of claim 15, wherein each EIS further comprises: a channel provided from one or more materials with a tunable electronic conductivity that is determined by an ion concentration; an electrolyte disposed over the channel; and an ion reservoir disposed over the electrolyte, wherein in response to a non-zero electrical stimulus one or more ions are released from the ion reservoir.

18. The hybrid electronic-ionic circuit of claim 17, wherein each EIS further comprises: a source disposed over a first end of the channel; a drain disposed over a second opposing end of the channel; and a gate disposed over the ion reservoir.

19. The hybrid electronic-ionic circuit of claim 18, wherein a voltage divider circuit is disposed over the gate to form a coincidence detector (AND-gate).

20. The hybrid electronic-ionic circuit of claim 19, wherein a conductance of the channel can be read out by measuring current flowing through the channel with a fixed bias voltage across the source and the drain or by the voltage divider circuit.
